(19) United States
(12) Patent Application Publication
(10) Pub. No.: US 2008/0160696 A1
(43) Pub. Date: Jul. 3, 2008

(54) METHOD FOR FABRICATING FLASH MEMORY DEVICE

(76) Inventor: Young Wook Shin, Seoul (KR)

Correspondence Address: SHERR & NOURSE, PLLC, 620 HERNDON PARKWAY, SUITE 200, HERNDON, VA, 20170, US

(21) Appl. No.: 11/616,823

(22) Filed: Dec. 27, 2006

(51) Int. Cl. H01L 21/336

(52) U.S. Cl. 438/266; 257/E21.422

(57) ABSTRACT

A method for fabricating a flash memory device, includes: preparing a substrate having an active region and an inactive region; forming a trench in the inactive region; forming a device isolation film in the trench; forming a well in the active region; forming a tunnel oxide film, a first polysilicon layer, an inter-layer dielectric film, a second polysilicon layer, and an oxide film over a surface of the substrate having the well formed therein; and forming a floating gate, a dielectric film, a control gate and a protection film over the active region by patterning the first polysilicon layer, the inter-layer dielectric film, the second polysilicon layer and the oxide film. The method further includes: forming a photoresist pattern over the surface of the substrate to thereby expose the protection film and the inactive region; and removing the exposed tunnel oxide film and the device isolation film over the inactive region using the photoresist pattern. The protection film protects the floating and control gates from becoming damaged during an etching step.

### FIELD OF THE INVENTION

The present invention relates to a flash memory device, and more particularly, to a method for fabricating a flash memory device capable of preventing a control gate from being damaged.

### BACKGROUND OF THE INVENTION

Generally, semiconductor memory devices can be divided into volatile RAM products, such as DRAM (Dynamic Random Access Memory) and SRAM (Static Random Access Memory), which lose data when turned off and which have high speed data input and output, and ROM (Read Only Memory) products, which input and output at a low speed, but can retain data when turned off. Such ROM products can be classified into ROM, PROM (Programmable ROM), EPROM (Erasable PROM) and EEPROM (Electrically EPROM). Demand is increasing for EEPROM particularly. EEPROM cells or flash memory cells have a block erase function, accomplished with a stacked gate structure including a floating gate, a dielectric film and a control gate.

Hereinafter, a method for fabricating a flash memory device will be described with reference to attached drawings.

FIGS. 1a and 1b are process sectional views showing a method for fabricating a flash memory device.

First, referring to FIG. 1a, a tunnel oxide film 103, a floating gate 104, a dielectric film 105, and a control gate 106 are formed over a substrate 100 in which a trench 101 has a device isolation film 102 formed therein.

A photoresist pattern PR is formed over the entire surface of the substrate 100, with a part of the control gate 106 and an inactive region exposed. A part of the control gate 106 is exposed is to maximize the exposed area of the device isolation film 102. By doing this, the device isolation film 102 may be etched thoroughly.

Referring to FIG. 1b, the tunnel oxide film 103 and the device isolation film 102 of the inactive region are removed using the photoresist pattern PR as a mask.

However, during the etching process, a part of the control gate 106 is etched since it is exposed.

Accordingly, when impurities are implanted to form a source diffusion layer in the exposed trench 101, the impurities also penetrate the control gate 106 through the etched part of the control gate 106.

When impurities penetrate the control gate, they form an unnecessary electronic trap, so that the cell does not function normally. Ultimately, erasure, programming and reading operations in the resulting device may be affected.

### SUMMARY OF THE INVENTION

Embodiments relate to a flash memory device, and more particularly, to a method for fabricating a flash memory device capable of preventing a control gate from being damaged.

Embodiments relate to a protection film formed over a control gate so as to prevent the control gate from being damaged when etching a source region of a flash cell.

Embodiments relate to a protection film over a control gate which prevents a tunnel oxide film and a dielectric film from being affected by a source etching process in the flash cell, thereby making the cell resistant to a word line stress or other stress tests.

Embodiments relate to removing defects such as particles and polymers while removing a protection film over a control gate after forming the source region of a flash cell, thereby enhancing the yield.

Embodiments relate to a method for fabricating a flash memory device, comprising: preparing a substrate having active regions and inactive regions therein; forming a trench in the inactive region; forming a device isolation film in the trench; forming a well in the active region; sequentially forming a tunnel oxide film, a first polysilicon layer, an inter-layer dielectric film, a second polysilicon layer, and an oxide film over the entire surface of the substrate; forming a floating gate, a dielectric film, a control gate and a protection film over the active region by patterning the first polysilicon layer, the inter-layer dielectric film, the second polysilicon layer and the oxide film; forming a photoresist pattern over the entire surface of the substrate so as to expose the protection film and the inactive region; and removing the exposed tunnel oxide film and the device isolation film over the inactive region using the photoresist pattern as a mask.

The dielectric film may be formed by sequentially stacking the first oxide film, the nitride film and the second oxide film.

The protection film may be formed of an oxide or nitride film with a thickness of about 50 Å. The floating gate and the control gate may be formed of polysilicon.

The method may further comprise removing the protection film.

### BRIEF DESCRIPTION OF THE DRAWINGS

FIGS. 1a and 1b are process sectional views showing a conventional method for fabricating a flash memory device.

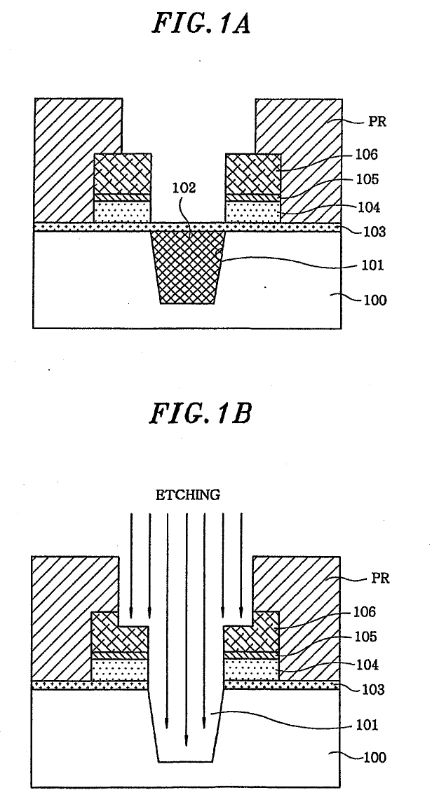

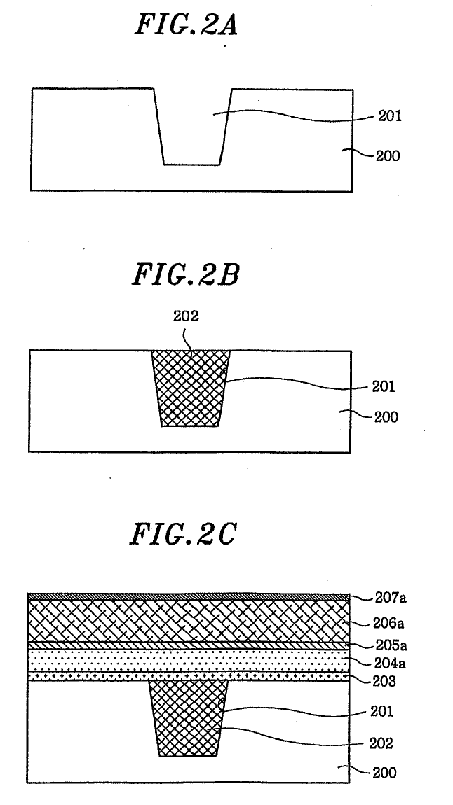

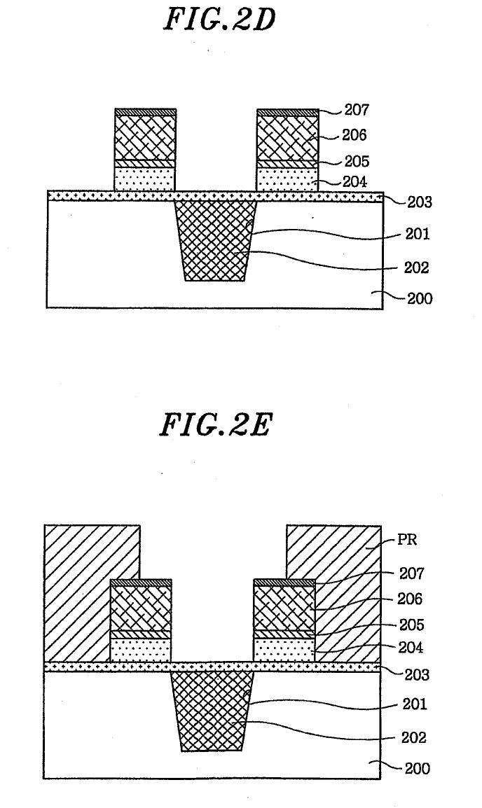

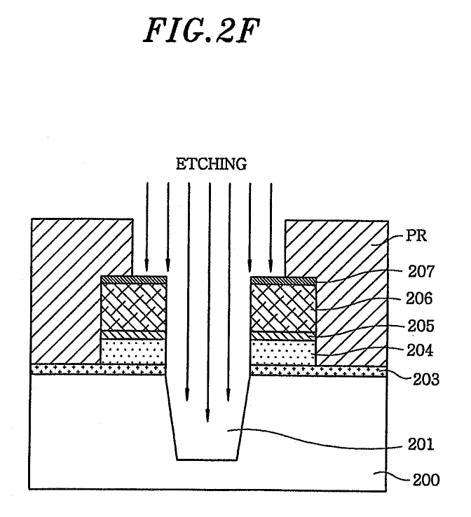

Example FIGS. 2a to 2f are process sectional views showing a method for fabricating a flash memory device in accordance with embodiments.

### DETAILED DESCRIPTION OF THE PREFERRED EMBODIMENTS

Referring to FIG. 2a, a trench 201 is formed with a desired depth in an inactive region of a substrate 200 which has both active and inactive regions.

Referring to FIG. 2b, a device isolation film 202 is formed in the trench 201.

Subsequently, a well may be formed in the active region of the substrate 200 by implanting impurities, though it is not shown in the figure.

Referring to FIG. 2c, a gate oxide film of a unit cell is formed by growing an oxide film 203 (or, a nitride film) about 96 Å thick over an entire surface of the substrate 200 to be used as a tunnel oxide film. A first electrode layer, for example, a first polysilicon layer 204a, is evaporated over the gate oxide film with a thickness of about 1000 Å to be used as a floating gate.

Subsequently, a first polysilicon layer 204a is doped with n⁺-type impurities by depositing phosphoroxidchloride (POCl₃) including an amount of Phosphor (P).

Next, a first oxide film having a thickness of about 60 Å is grown by oxidizing the first polysilicon layer 204a. A nitride film having a thickness of about 80 Å is evaporated over the first oxide film and oxidized so as to grow a second oxide film having a thickness of about 60 Å. At this point, an inter-layer dielectric film 205a composed of ONO (Oxide/Nitride/Oxide) has formed.

Then, a second electrode layer to be used as a control gate is formed over the inter-layer dielectric film 205a. The second electrode layer is a second polysilicon layer 206a doped with n⁺-type impurities having a thickness of 2100 Å, for example.

An oxide film 207a (or a nitride film) is formed over the second poly-silicon layer 206a. The oxide film 207a may be formed through a high density plasma chemical vapor deposition process at a temperature of about 780° C. The oxide film 207a may also be formed as a thermal oxide film by keeping the temperature at about 780° C. for about 10 minutes. Its thickness may be from 20 Å to 80 Å, preferably, about 50 Å.

Then, as shown in FIG. 2d, a floating gate 204, a dielectric film 205, a control gate 206 and a protection film 207 are formed over the active region of the substrate 200 by patterning the oxide film 207a, the second polysilicon film 206a, the inter-layer dielectric film 205 and the first polysilicon layer 204a using photoresist and etching processes.

Here, the floating gate 204, the dielectric film 205, the control gate 206 and the protection film 207 are formed over the tunnel oxide film, the floating gate 204, the dielectric film 205 and the control gate 206, respectively.

Referring to FIG. 2e, a photoresist pattern PR is formed over the substrate 200, with a part of the protection film 207 and the inactive region exposed.

Referring to FIG. 2f, the tunnel oxide film 203 and the device isolation film 202 of the inactive region are successively etched and removed, using the photoresist pattern PR as a mask.

The protection film 207 protects the control gate 206 from damage in the source etching process. At the same time, the protection film 207 also prevents the tunnel oxide film 203 and the dielectric film 205 from being affected by the etching process, thereby making the cell able to withstand a stress test such as a word line stress.

The protection film 207 formed over the control gate 206 is removed after the etching process, and a source diffusion layer is formed by implanting ions under the exposed trench 201.

The protection film 207 is removed using a wet etching process, wherein a COM cleaning process is applied after processing the protection film 207 with DHF (Dilute HF, H₂O and HF mixed). The COM cleaning process is implemented by treating the protection film 207 with 4% Hcl for about 180 seconds and then with ozonated water, with about 5 ppm ozone, for about 600 seconds.

Here, the wet etching process to remove the protection film 207 removes defects such as particles and polymers, thereby enhancing yields.

As described above, the method for fabricating a flash memory device in accordance with embodiments may have the following effects.

The protection film is formed over the control gate to prevent the control gate from being damaged during the source etching process of the flash cell.

At the same time, the protection film over the control gate prevents the tunnel oxide film and the dielectric film from being affected by the source etching process of the flash cell, so that the cell can withstand a stress test such as a word line stress.

Further, when the protection film over the control gate is removed after forming the source of the flash cell, defects such as particles and polymers are also removed, so that the yield is enhanced.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
preparing a substrate having an active region and an inactive region therein;
forming a trench in the inactive region;
forming a device isolation film in the trench;
forming a well in the active region;
sequentially forming a tunnel oxide film, a first polysilicon layer, an inter-layer dielectric film, a second polysilicon layer, and an oxide film over a surface of the substrate having the well formed therein;
forming a floating gate, a dielectric film, a control gate and a protection film over the active region by patterning the first polysilicon layer, the inter-layer dielectric film, the second polysilicon layer and the oxide film;
forming a photoresist pattern over the surface of the substrate to expose the protection film and the inactive region; and
removing the exposed tunnel oxide film and the device isolation film over the inactive region using the photoresist pattern as a mask.

2. The method of claim 1, wherein the dielectric film is formed by sequentially stacking a first oxide film, a nitride film and a second oxide film.

3. The method of claim 1, wherein the protection film is formed with a thickness of about 50 Å.

4. The method of claim 1, further comprising removing the protection film.

5. The method of claim 1, wherein the protection film is formed of an oxide film.

6. The method of claim 1, wherein the floating gate and the control gate are formed of polysilicon.

7. The method of claim 1, further comprising the formation of a flash memory cell.

8. The method of claim 1, wherein the protection film is formed of a nitride film.
